(19) United States
(12) Patent Application Publication
(10) Pub. No.: US 2023/0217734 A1
(43) Pub. Date: Jul. 6, 2023

(54) ELECTROLUMINESCENCE DISPLAY

(71) Applicant: LG Display Co., Ltd., Seoul (KR)

(72) Inventors: SangHoon LEE, Paju-si (KR); HanSol CHOI, Paju-si (KR)

(73) Assignee: LG Display Co., Ltd., Seoul (KR)

(21) Appl. No.: 18/051,031

(22) Filed: Oct. 31, 2022

(30) Foreign Application Priority Data
Dec. 30, 2021 (KR) 10-2021-0192871

(51) Int. Cl. H01L 27/32; H01L 51/52

(52) U.S. Cl. CPC H01L 27/3258; H01L 51/5237

(57) ABSTRACT

An electroluminescence display having a robust structure against the penetration of hydrogen particles includes a substrate including a display area and a non-display area, the non-display area surrounding the display area; a light emitting element disposed in the display area; a gate driver disposed at the non-display area; a slit pattern overlapping with the gate driver; and a protection pattern overlapping with an empty space of the gate driver in the slit pattern, the slit pattern has a shape of a trench which is formed at a planarization layer covering the gate driver, and the protection pattern includes a same material as a part of the light emitting element and a part of the gate driver.

### CROSS-REFERENCE TO RELATED APPLICATION

This application claims the priority of Korean Patent Application No. 10-2021-0192871 filed on Dec. 30, 2021, which is hereby incorporated by reference in its entirety.

### BACKGROUND

### Field of the Disclosure

The present disclosure relates to an electroluminescence display. More particularly, the present disclosure relates to an electroluminescence display having a robust structure against the penetration of hydrogen particles.

### Description of the Background

Among display devices, an electroluminescence display device is a self-light emitting device, and has advantages in that a viewing angle and a contrast ratio are more excellent than those of other display devices. Further, since the electroluminescence display device does not require a separate backlight, it is advantageous that the electroluminescence display device is able to be thin and lightweight and has low power consumption. Furthermore, an organic light emitting display device of the electroluminescence display device has advantages in that it can be driven at a low direct current voltage, has a fast response speed, and has a low manufacturing cost.

The electroluminescence display device includes a plurality of electroluminescence diodes. The electroluminescence diode includes an anode electrode, a light emitting layer formed on the anode electrode, and a cathode electrode formed on the light emitting layer. If a high potential voltage is applied to the anode electrode and a low potential voltage is applied to the cathode electrode, holes in the anode electrode and electrons in the cathode electrode respectively move to the light emitting layer. When holes and electrons are combined with each other in the light emitting layer, exciton is formed during an excitation process, and light is generated due to the energy from the exciton. The electroluminescence display device displays an image by electrically controlling the amount of light generated from the light emitting layers of the plurality of electroluminescence diodes partitioned by banks.

An encapsulation layer may be included to protect various elements of the electroluminescence display from oxygen or moisture intruded from outside. Meanwhile, the semiconductor device may be deteriorated as it is used for a long time due to diffusion of hydrogen particles generated in the process of manufacturing silicon nitride configuring the encapsulation layer and the insulating layer. The electroluminescence display requires a structure capable of preventing moisture from penetrating from the outside and blocking the hydrogen particles that may diffuse inside of the elements.

### SUMMARY

Accordingly, the present disclosure is to provide an electroluminescence display including an insulating layer for preventing foreign materials from intruding from the outside environment.

The present disclosure is also to provide an electroluminescence display having a structure that prevents hydrogen particles from diffusing inside an insulating layer to adversely affect a semiconductor device for forming an internal insulating layer.

To achieve the above described, an electroluminescence display device according to an aspect of the present disclosure includes a substrate including a display area and a non-display area, the non-display area surrounding the display area; a light emitting element disposed in the display area; a gate driver disposed at the non-display area; a slit pattern overlapping with the gate driver; and a protection pattern overlapping with an empty space of the gate driver in the slit pattern. The slit pattern has a shape of a trench which is formed at a planarization layer covering the gate driver. The protection pattern includes a same material as a part of the light emitting element and a part of the gate driver.

In one example, the gate driver comprises a plurality of thin film transistors. The slit pattern overlaps with the thin film transistors and empty spaces where there is no thin film transistor. The protection pattern overlaps with the slit pattern which overlaps with the empty spaces.

In one example, the light emitting element includes: a pixel driving electrode disposed on the planarization layer; a bank defining an emission area at middle portions of the pixel driving electrode; an emission layer on the pixel driving electrode; and a common electrode on the emission layer. The protection pattern covers the slit pattern, is disposed on a passivation layer covering the gate driver, and includes a same material as the pixel driving electrode. The bank includes a contact hole exposing a central portion of the protection pattern. The common electrode extends from the display area to the non-display area for contacting the protection pattern via the contact hole.

In one example, the protection pattern includes: a first layer including a same material as an element of the gate driver; and a second layer including a same material as the pixel driving electrode on the first layer. The second layer contact the first layer.

In one example, the first layer includes at least one of molybdenum, titanium and molybdenum-titanium alloy.

In one example, the first layer is disposed on a gate insulating layer covering the substrate, and includes same material with a gate electrode of the gate driver. The second layer contact the first layer through the intermediate insulating layer and the passivation layer covering the first layer.

In one example, the first layer is disposed on an intermediate insulating layer covering the substrate, and includes same material with a source electrode of the gate driver. The second layer contact the first layer through the passivation layer covering the first layer.

In one example, the protection pattern includes: a first layer including same material with a gate electrode of the gate driver; a second layer including same material with a source electrode of the gate driver, on the first layer; and a third layer including same material with the pixel driving electrode, on the second layer. The second layer and the third layer contact the first layer.

In one example, the second layer contacts a central portion of the first layer, and exposes circumference portion of the first layer. The third layer contacts the exposed circumference portion of the first layer and the second layer.

In one example, the first layer and the second layer have same shape. A portion of the first layer is exposed from circumference of the second layer. The third layer contacts the second layer, and the exposed portion of the first layer from the second layer.

In one example, the first layer and the second layer include at least one of molybdenum, titanium and molybdenum-titanium alloy.

In one example, the first layer includes: a first metal layer formed on the gate insulating layer; and a second metal layer formed on the first metal layer. The first metal layer is exposed from circumference of the second layer and the second metal layer. The third layer contacts the second layer, and the exposed portion of the first metal layer from the second layer and the second metal layer.

In one example, the first metal layer includes at least one of molybdenum, titanium and molybdenum-titanium alloy. The second metal layer includes at least one of aluminum and copper.

In one example, the electroluminescence display further comprises: a dam disposed outside of the gate driver in the non-display area, and surrounding the display area; and an encapsulation layer on the common electrode.

In one example, the encapsulation layer includes: a first inorganic encapsulation layer covering the display area and the non-display area, an inside wall surface of the dam, an upper surface of the dam, and an outer wall surface of the dam; an organic encapsulation layer disposed on the first inorganic encapsulation layer, and contacting a portion of the inside wall surface of the dam; and a second inorganic encapsulation layer disposed on the organic encapsulation layer, and contacting the first inorganic encapsulation layer at the upper surface of the dam and the outer wall surface of the dam.

In one example, an electroluminescence display apparatus comprises: a substrate including a display area and a non-display area, the non-display area surrounding the display area; a gate driver and a slit pattern disposed at the non-display area, wherein the gate driver includes a plurality of thin film transistors, and the slit pattern is disposed over the thin film transistors and empty spaces where there is no thin film transistor; and a protection pattern covering the slit pattern located over the empty spaces, and includes at least one of molybdenum, titanium and molybdenum-titanium alloy.

The electroluminescence display device according to one aspect of the present disclosure may include various insulating layers provided to protect and insulate internal elements. These insulating layers may be formed of nitride materials such as silicon nitride in order to ensure protection. However, in case of nitride layer, the hydrogen particles may be emitted and diffused during the manufacturing process, and the diffusion of hydrogen particles may deteriorate the properties of the oxide semiconductor material. In the present disclosure, it is possible to obtain the effect of protecting the properties of the oxide semiconductor material by trapping and suppressing diffusible hydrogen particles using a patterned layer formed of molybdenum and/or titanium. In particular, in the narrow bezel structure in which the edge area of the display panel is narrowly formed, the width of the bezel area may not secure a sufficiently long path for foreign materials to penetrate from the outside, so a nitride insulating layer and a protective layer may be applied. In the present disclosure, the oxide semiconductor element may be protected by applying a structural element for trapping hydrogen particles and suppressing diffusion through the nitride insulating layer and the protection layer.

In addition to the effects of the present disclosure as mentioned above, additional features of the present disclosure will be clearly understood by those skilled in the art from the following description of the present disclosure.

### BRIEF DESCRIPTION OF THE DRAWINGS

The accompanying drawings, which are included to provide a further understanding of the disclosure and are incorporated in and constitute a part of the present disclosure, illustrate aspects of the disclosure and together with the description serve to explain the principle of the disclosure.

In the drawings:

FIG. 1 is a plane view illustrating a structure of an electroluminescence display according to the present disclosure.

FIG. 2 is a cross-sectional view, along cutting line I-I′ in FIG. 1, illustrating a structure of an electroluminescence display according to the present disclosure.

FIG. 3 is an enlarged plan view, illustrating a structure of a gate driver in the circular ‘V’ portion of FIG. 1.

FIG. 4 is an enlarged cross-sectional view of portion where a protection pattern is formed, along cutting line II-IF in FIG. 1, illustrating a structure of an electroluminescence display according to the present disclosure.

FIG. 5 is a cross-sectional view, along cutting line in FIG. 3, illustrating a structure of an electroluminescence display according to the first aspect of the present disclosure.

FIG. 6 is a cross-sectional view, along cutting line in FIG. 3, illustrating a structure of an electroluminescence display according to the second aspect of the present disclosure.

FIG. 7 is a cross-sectional view, along cutting line in FIG. 3, illustrating a structure of an electroluminescence display according to the third aspect of the present disclosure.

FIG. 8 is a cross-sectional view, along cutting line in FIG. 3, illustrating a structure of an electroluminescence display according to the fourth aspect of the present disclosure.

FIG. 9 is a cross-sectional view, along cutting line in FIG. 3, illustrating a structure of an electroluminescence display according to the fifth aspect of the present disclosure.

FIG. 10 is a cross-sectional view, along cutting line in FIG. 3, illustrating a structure of an electroluminescence display according to the sixth aspect of the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only-’ is used. The terms of a singular form can include plural forms unless referred to the contrary.

In construing an element, the element is construed as including an error range although there is no explicit description.

In describing a position relationship, for example, when the position relationship is described as ‘upon-%’, ‘above-’, ‘below-%’, and ‘next to-’, one or more portions can be arranged between two other portions unless ‘just’ or ‘direct’ is used.

In describing a time relationship, for example, when the temporal order is described as ‘after-’, ‘subsequent-’, ‘next-’, and ‘before-%’, a case which is not continuous can be included unless ‘just’ or ‘direct’ is used.

It will be understood that, although the terms “first”, “second”, etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Hereinafter, an example of an electroluminescence display device according to the present disclosure will be described in detail with reference to the accompanying drawings. Wherever possible, the same reference numbers will be used throughout the drawings to refer to the same or like parts.

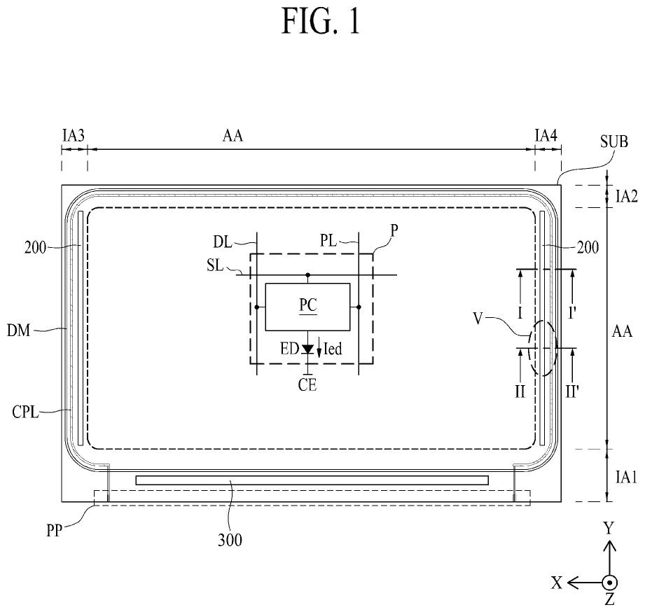

FIG. 1 is a plane view illustrating a structure of an electroluminescence display according to the present disclosure. Referring to FIG. 1, the electroluminescence display device according to the present disclosure may include a substrate SUB, a pixel P, a common power line CPL, a gate driving circuit 200, a dam DM and a driving integrated circuit 300.

The substrate SUB is a base substrate (or base layer), and includes a plastic material or a glass material. In view of characteristics of a display device, the substrate SUB may be transparent. The substrate SUB according to one example can have a rectangular shape, a rounded rectangular shape, each of whose corner portions is rounded with a certain curvature radius, or a non-rectangular shape having at least six sides, on a plane. In this case, the substrate SUB having a non-rectangular shape can include at least one protrusion or at least one notch portion.

The substrate SUB according to one example can be categorized into a display area AA and a non-display area IA. The display area AA is provided at most of center portions of the substrate SUB, and can be defined as an area for displaying an image. The display area AA according to one example can have a rectangular shape, a rounded rectangular shape, each of whose corner portions is rounded with a certain curvature radius, or a non-rectangular shape having at least six sides, on a plane. In this case, the display area AA having a non-rectangular shape can include at least one protrusion or at least one notch portion.

The non-display area IA is provided on an edge area of the substrate SUB to surround the display area AA, and can be defined as an area where an image is not displayed, or a peripheral area. The non-display area IA according to one example can include a first non-display area IA1 provided on a first edge of the substrate SUB, a second non-display area IA2 provided on a second edge of the substrate SUB in parallel with the first non-display area IA1, a third non-display area IA3 provided on a third edge of the substrate SUB, and a fourth non-display area IA4 provided on a fourth edge of the substrate SUB in parallel with the third non-display area IA3. For example, the first non-display area IA1 can be, but is not limited to, an upper (or lower) edge area of the substrate SUB, the second non-display area IA2 can be, but is not limited to, a lower (or upper) edge area of the substrate SUB, the third non-display area IA3 can be, but is not limited to, a left (or right) edge area of the substrate SUB, and the fourth non-display area IA4 can be, but is not limited to, a right (or left) edge area of the substrate SUB.

A plurality of pixels P can be provided on the display area AA of the substrate SUB. The pixels P according to one example can be a plurality of pixels arranged in a matrix arrangement, and can be arranged in the display area AA of the substrate SUB. The pixels P can be defined by scan lines SL, data lines DL, and pixel driving power lines PL.

The scan lines SL are extended along a first direction X and arranged along a second direction Y crossing the first direction X at a certain interval. The display area AA of the substrate SUB includes a plurality of scan lines SL that are spaced apart from one another along the second direction Y and extended in parallel with the first direction X. In this case, the first direction X can be defined as a horizontal direction of the substrate SUB and the second direction Y can be defined as a vertical direction of the substrate SUB, or vice versa without limitation to this case.

The data lines DL are extended along the second direction Y and arranged along the first direction X at a certain interval. The display area AA of the substrate SUB includes a plurality of data lines DL that are spaced apart from one another along the first direction X and extended in parallel with the second direction Y.

The pixel driving power line PL can be arranged on the substrate SUB to be parallel with the data line DL. The display area AA of the substrate SUB includes a plurality of pixel driving power lines PL parallel with the data lines DL. Optionally, the pixel driving power lines PL can be arranged to be parallel with the scan lines SL.

The pixels P according to one example can be arranged on the display area AA to have a stripe structure. In this case, one-unit pixel can include a red subpixel, a green subpixel, and a blue subpixel. Moreover, one-unit pixel can further include a white subpixel.

The pixels P according to another example can be arranged on the display area AA to have a pentile structure. In this case, one-unit pixel can include at least one red subpixel, at least two green subpixels, and at least one blue pixel, which are arranged in a polygonal shape two-dimensionally. For example, one-unit pixel having a pentile structure can be arranged such that one red subpixel, two green subpixels and one blue subpixel have an octagonal shape two-dimensionally. In this case, the blue subpixel can have an opening area (or light emitting area) which is relatively the greatest, and the green subpixel can have an opening area which is relatively the smallest.

The pixel P can include a pixel circuit PC electrically connected with its adjacent scan line SL, a data line DL and a driving power line PL, and a light emitting diode ED electrically connected with the pixel circuit PC.

The pixel circuit PC controls a current Ied flowing from the pixel driving power line PL to the light emitting diode ED based on a data voltage supplied from its adjacent data line DL in response to a scan signal supplied from at least one scan line SL adjacent thereto.

The pixel circuit PC according to one example can include at least two thin film transistors and one capacitor. For example, the pixel circuit PC according to one example can include a driving thin film transistor supplying the data current Ted based on the data voltage to the light emitting diode ED, a switching thin film transistor supplying the data voltage supplied from the data line DL to the driving thin film transistor, and a capacitor storing a gate-source voltage of the driving thin film transistor.

The pixel circuit PC according to another example can include at least three thin film transistors and at least one capacitor. For example, the pixel circuit PC according to another example can include a current supply circuit, a data supply circuit and a compensation circuit in accordance with an operation (or function) of each of at least three thin film transistors. In this case, the current supply circuit can include a driving thin film transistor supplying the data current Ted based on the data voltage to the light emitting diode ED. The data supply circuit can include at least one switching thin film transistor supplying the data voltage supplied from the data line DL to the current supply circuit in response to at least one scan signal. The compensation circuit can include at least one compensation thin film transistor compensating for a change of a characteristic value (threshold voltage and/or mobility) of the driving thin film transistor in response to at least one scan signal.

The light emitting diode ED emits the light of luminance corresponding to the data current Ted supplied from the pixel circuit PC. In this case, the data current Ted can flow from the driving power line PL to the common power line CPL through the driving thin film transistor and the light emitting diode ED.

The light emitting diode ED according to one example can include a pixel driving electrode (not shown) (or first electrode or anode) electrically connected with the pixel circuit PC, a light emitting layer (not shown) formed on the pixel driving electrode, and a common electrode CE (or second electrode or cathode) electrically connected with the light emitting layer.

The common power line CPL is arranged on the non-display area IA of the substrate SUB and electrically connected with the common electrode CE arranged on the display area AA. The common power line CPL according to one example is arranged along the second to fourth non-display areas IA2, IA3 and IA4 adjacent to the display area AA of the substrate SUB while having a certain line width, and surrounds the other portion except a portion of the display area AA adjacent to the first non-display area IA1 of the substrate SUB. One end of the common power line CPL can be arranged on one side of the first non-display area IA1, and the other end of the common power line CPL can be arranged on the other side of the first non-display area IA1. Therefore, the common power line CPL according to one example can two-dimensionally have a ‘∩’ shape of which one side corresponding to the first non-display area IA1 of the substrate SUB is opened.

An encapsulation layer can be formed on the substrate SUB to surround an upper surface and a side of the display area AA and the common power line CPL. Meanwhile, the encapsulation layer can expose one end and the other end of the common power line CPL in the first non-display area IA1. The encapsulation layer can prevent oxygen or water from permeating into the light emitting diode ED provided in the display area AA. The encapsulation layer according to one example can include at least one inorganic film. The encapsulation layer according to another example can include a plurality of inorganic films and organic films interposed among the plurality of inorganic films.

The electroluminescence display device according to one aspect of the present disclosure may include a pad portion PP, a gate driving circuit 200, and a driving integrated circuit 300.

The pad portion PP can include a plurality of pads provided in the non-display area IA of the substrate SUB. The pad portion according to one example can include a plurality of common power supply pads, a plurality of data input pads, a plurality of power supply pads and a plurality of control signal input pads, which are provided in the first non-display area IA1 of the substrate SUB.

The gate driving circuit 200 is provided in the third non-display area IA3 and/or the fourth non-display area IA4 of the substrate SUB and connected with the scan lines SL provided in the display area AA in a one-to-one relationship. The gate driving circuit 200 can be integrated with the third non-display area IA3 and/or the fourth non-display area IA4 of the substrate SUB together with a manufacturing process of the pixel P, that is, a manufacturing process of the thin film transistor. The gate driving circuit 200 generates a scan signal based on a gate control signal supplied from the driving integrated circuit 300 and output the scan signal in accordance with a given order, thereby driving each of the plurality of scan lines SL in accordance with a given order. The gate driving circuit 200 according to one example can include a shift register.

The dam DM can have a closed curve structure in which it is provided in the first non-display area IA1, the second non-display area IA2, the third non-display area IA3 and the fourth non-display area IA4 of the substrate SUB to surround the periphery of the display area AA. For example, the dam DM can be arranged outside the common power line CPL and therefore located at the outermost above the substrate SUB. The pad portion PP and the driving integrated circuit 300 may be arranged in an outer area of the dam DM.

Although FIG. 1 shows that the dam DM is arranged at the outermost, the dam DM is not limited to the example of FIG. 1. As another example, the dam DM may be arranged between the common power line CPL and the gate driving circuit 200. As other example, the dam DM may be arranged between the display area AA and the gate driving circuit 200.

The driving integrated circuit 300 is packaged in a chip packaging area defined in the first non-display area IA1 of the substrate SUB through a chip packaging (bonding) process. Input terminals of the driving integrated circuit 300 are electrically connected with the pad portion PP and therefore electrically connected with the plurality of data lines DL and the plurality of pixel driving power lines PL, which are provided in the display area AA. The driving integrated circuit 300 receives various power sources, timing synchronizing signals and digital image data, which are input from a display driving circuit portion (or host circuit) through the pad portion PP, controls driving of the gate driving circuit 200 by generating a gate control signal in accordance with the timing synchronizing signals and at the same time converts the digital image data to an analog type pixel data voltage to supply the converted data voltage to the corresponding data line DL.

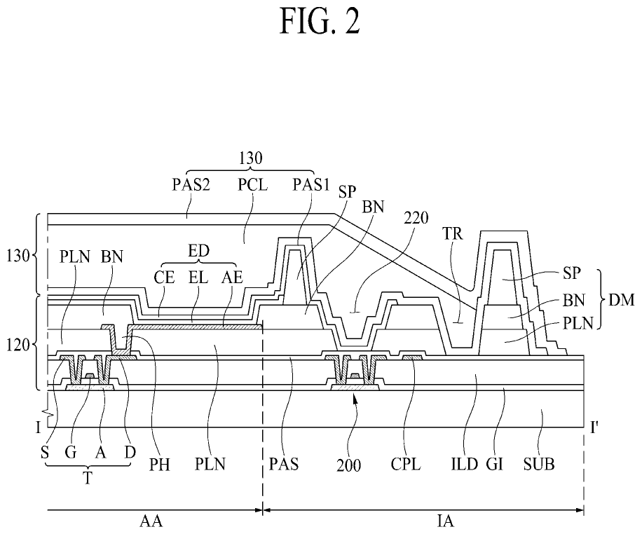

It will be described with reference to FIG. 2, a cross-sectional view, illustrating the structural features. FIG. 2 is a cross-sectional view, along cutting line I-I′ in FIG. 1, illustrating a structure of an electroluminescence display according to the first aspect of the present disclosure.

The electroluminescence display device according to the present disclosure may include a substrate SUB, a pixel array layer 120, a spacer SP and an encapsulation layer 130.

The substrate SUB is a base layer, and includes a plastic material or a glass material. The substrate SUB according to one example may have an opaque or colored polyimide material. The substrate SUB may include a display area AA and a non-display area IA. The non-display area IA may surround the display area AA.

A buffer film (not shown) may be formed on an upper surface of the substrate SUB. The buffer film is formed on one surface of the substrate SUB to shield water from permeating into the pixel array layer 120 through the substrate SUB vulnerable to water permeation. The buffer layer may be omitted.

The pixel array layer 120 may include a thin film transistor layer, a planarization layer PLN, a bank pattern BN, and a light emitting diode ED. The thin film transistor layer may have a plurality of thin film transistors formed at a plurality of pixels P defined in the display area AA, and at the gate driver 200 disposed at the 4th non-display area IA4 of the substrate SUB.

The driving layer 200 according to one example may include a thin film transistor T, a gate insulating film GI, an intermediate insulating layer ILD, and a passivation layer PAS. In this case, the thin film transistor T shown in FIG. 2 may be a driving thin film transistor electrically connected with the light emitting diode ED.

The thin film transistor T includes a semiconductor layer A, a gate electrode G, a source electrode S and a drain electrode D, which are formed on the substrate SUB or the buffer film. FIG. 2 show, but is not limited to, a top gate structure of the thin film transistor T, in which the gate electrode G is arranged above the semiconductor layer A. For another example, the thin film transistor T may have a bottom gate structure in which the gate electrode G is arranged below the semiconductor layer A, or a double gate structure in which the gate electrode G is arranged above and below the semiconductor layer A.

The semiconductor layer A may be formed on the substrate SUB or the buffer film. The semiconductor layer A may include a silicon-based semiconductor material, an oxide-based semiconductor material, or an organic based semiconductor material, and may have a single layered structure or a multi-layered structure. A light shielding layer for shielding external light entering the semiconductor layer A may additionally be formed between the buffer film and the semiconductor layer A.

The gate insulating film GI may be formed on the entire substrate SUB to cover the semiconductor layer A. The gate insulating film GI may be formed of an inorganic film, for example, a silicon oxide (SiOx) film, a silicon nitride (SiNx) film, or a multi-layered film of SiOx and SiNx.

The gate electrode G may be formed on the gate insulating film GI to overlap with the semiconductor layer A. The gate electrode G may be formed together with the scan line SL. The gate electrode G according to one example may be formed of a single layer or multi-layer of any one of Mo, Al, Cr, Au, Ti, Ni, Nd, and Cu, or their alloy.

The intermediate insulating layer ILD may be formed on the entire substrate SUB to cover the gate electrode G and the gate insulating film GI. The intermediate insulating layer ILD provides a planarization plane on the gate electrode G and the gate insulating film GI.

The source electrode S and the drain electrode D may be formed on the intermediate insulating layer ILD to overlap with the semiconductor layer A. The gate electrode G is interposed between the source electrode S and the drain electrode D. The source electrode S and the drain electrode D may be formed together with the data line DL, the driving power line PL and the common power line CPL. For instance, the source electrode S, the drain electrode D, the data line DL, the driving power line PL and the common power line CPL are respectively formed by a patterning process for a source-drain electrode material at the same time.

Each of the source electrode S and the drain electrode D may be connected to the semiconductor layer A through an electrode contact hole that passes through the intermediate insulating layer ILD and the gate insulating film GI. The source electrode S and the drain electrode D may be formed of a single layer or multi-layer of any one of Mo, Al, Cr, Au, Ti, Ni, Nd, and Cu, or their alloy. In this case, the source electrode S of the thin film transistor T shown in FIG. 2 may electrically be connected with the pixel driving power line PL shown in FIG. 1.

As described above, the thin film transistor T provided in the pixel P of the substrate SUB constitutes a pixel circuit PC. Also, the gate driving circuit 200 arranged in the fourth non-display area IA4 of the substrate SUB may include a thin film transistor the same as or similar to the thin film transistor T provided in the pixel P.

The passivation layer PAS is deposited on the substrate SUB for protecting the thin film transistor T. The passivation layer PAS is stacked as covering all thin film transistors T formed at the display area AA and at the gate driver 200.

The planarization layer PLN is formed on the entire substrate SUB to cover the thin film transistor layer. The planarization layer PLN provides a planarization surface on the thin film transistor layer. The planarization layer PLN according to one example may be formed of an organic film include acrylic resin, epoxy resin, phenolic resin, polyamide resin, or polyimide resin.

The planarization layer PLN according to another example can include a pixel contact hole PH for exposing the drain electrode D of the driving thin film transistor provided in the pixel P.

The bank BN is arranged on the planarization layer PLN and defines an opening area (or light emitting area) inside the pixel P of the display area AA. The bank BN may be expressed as a pixel defining film.

The light emitting diode ED may include a pixel driving electrode AE, a light emitting layer EL, and a common electrode CE. The pixel driving electrode AE is formed on the planarization layer PLN and electrically connected to the drain electrode D of the driving thin film transistor through the pixel contact hole PH provided in the planarization layer PLN. In this case, the other edge portion except a center portion of the pixel driving electrode AE overlapping with the opening area of the pixel P may be covered by the bank BN. The bank BN may define an opening area of the pixel P by covering the edge portion of the pixel driving electrode AE.

The pixel driving electrode AE according to one example can include a metal material of high reflectivity. For example, the pixel driving electrode AE can be formed of a multi-layered structure such as a deposited structure (Ti/Al/Ti) of aluminum (Al) and titanium (Ti), a deposited structure (ITO/Al/ITO) of Al and ITO, an APC (Ag/Pd/Cu) alloy, and a deposited structure (ITO/APC/ITO) of APC alloy and ITO, or can include a single layered structure made of a material of any one or an alloy material of two or more selected from Ag, Al, Mo, Au, Mg, Ca and Ba.

The light emitting layer EL is entirely formed on the display area AA of the substrate SUB to cover the pixel driving electrode AE and the bank pattern BN. The light emitting layer EL according to one example can include two or more light emitting portions vertically deposited to emit a white light. For example, the light emitting layer EL according to one example can include first and second light emitting portions for emitting a white light by combination of a first light and a second light. Here, the first light emitting portions, as for generating a first light, may include any one of blue light emitting portion, green light emitting portion, red light emitting portion, yellow light emitting portion and yellow-green light emitting portion. The second light emitting portion, as for generating a second light having a complementary color to the first light, may include any one of blue light emitting portion, green light emitting portion, red light emitting portion, yellow light emitting portion and yellow-green light emitting portion.

The light emitting layer EL according to another example may include any one of a blue light emitting portion, a green light emitting portion and a red-light emitting portion to emit a color light corresponding to a color set in the pixel P. For example, the light emitting layer EL may include any one of an organic light emitting layer, an inorganic light emitting layer and a quantum-dot light emitting layer, or may include a deposited or combination structure of the organic light emitting layer (or the inorganic light emitting layer) and the quantum-dot light emitting layer.

Additionally, the light emitting diode ED according to one example may further include a functional layer for improving light emission efficiency and/or lifetime of the light emitting layer EL.

The common electrode CE is formed to be electrically connected with the light emitting layer EL. The common electrode CE is formed on the entire display area AA of the substrate SUB and therefore commonly connected with the light emitting layers EL provided in each pixel P. Further, the common electrode CE may extend to the non-display area IA over the display area AA.

The common electrode CE according to one example may include a transparent conductive material or a semi-transmissive conductive material, which may transmit light. When the common electrode CE is formed of a semi-transmissive conductive material, light emission efficiency of light emitted from the light emitting diode ED may be enhanced through a micro cavity structure. The semi-transmissive conductive material according to one example may include Mg, Ag, or an alloy of Mg and Ag. Additionally, a capping layer for improving emission efficiency of light by controlling a refractive index of light emitted from the light emitting diode ED may further be formed on the common electrode CE.

The spacer SP can be arranged to be distributed in an opening area inside the display area AA, that is, an area where the light emitting diode ED is not arranged. The spacer SP is intended to allow a screen mask and a substrate not to be in contact with each other during a process of depositing the light emitting layer EL. The spacer SP is arranged on the bank pattern BN, and can be deposited to allow the light emitting layer EL and the common electrode CE to overstride/cover the spacer SP arranged inside the display area AA.

As the case can be, the light emitting layer EL and/or the common electrode CE may not overstride the spacer SP. Since the spacer SP is arranged in only a portion of the bank pattern BN inside the display area AA, the common electrode CE has a structure connected with the display area AA while fully covering the display area AA even though the common electrode CE does not overstride the spacer SP.

The encapsulation layer 130 is formed to surround an upper surface and a side of the pixel array layer 120. The encapsulation layer 130 serves to prevent oxygen or water from permeating into the light emitting diode ED.

The encapsulation layer 130 according to one example may include a first inorganic encapsulation layer PAS1, an organic encapsulation layer PCL on the first inorganic encapsulation layer PAS1, and a second inorganic encapsulation layer PAS2 on the organic encapsulation layer PCL. The first inorganic encapsulation layer PAS1 and the second inorganic encapsulation layer PAS2 serve to shield water or oxygen from permeating into the light emitting diode ED. Each of the first inorganic encapsulation layer PAS1 and the second inorganic encapsulation layer PAS2 may be formed of an inorganic material such as a silicon nitride, an aluminum nitride, a zirconium nitride, a titanium nitride, a hafnium nitride, a tantalum nitride, a silicon oxide, an aluminum oxide, or a titanium oxide. The first inorganic encapsulation layer PAS1 and the second inorganic encapsulation layer PAS2 may be formed by a Chemical Vapor Deposition (CVD) process or an Atomic Layer Deposition (ALD) process.

The organic encapsulation layer PCL is surrounded by the first inorganic encapsulation layer PAS1 and the second inorganic encapsulation layer PAS2. The organic encapsulation layer PCL may be formed to be relatively thicker than the first inorganic encapsulation layer PAS1 and/or the second inorganic encapsulation layer PAS2 to adsorb and/or shield particles that may occur during a manufacturing process. The organic encapsulation layer PCL may be made of an organic material such as SiOCx (silicon oxy-carbon) acryl and epoxy resin. The organic encapsulation layer PCL may be formed by a coating process, for example, an ink-jet coating process or a slit coating process.

The electroluminescence display device according to the first aspect of the present disclosure may further include a dam (or dam structure) DM. The dam DM is arranged in the non-display area IA of the substrate SUB to prevent the organic encapsulation layer PCL from overflowing.

The dam DM according to one example may be arranged outside the display area AA, the gate driving circuit 200 which is arranged outside the display area AA, and the common power line CPL arranged outside the gate driving circuit 200. As the case may be, the dam DM may be arranged to overlap with an outer side of the common power line CPL. In this case, a width of the non-display area IA where the gate driving circuit 200 and the common power line CPL are arranged may be reduced to reduce a bezel width.

The dam DM according to the present disclosure includes a three-layer structure formed perpendicular to the substrate SUB. For example, the dam DM may include a first layer made of the planarization layer PLN, a second layer made of the bank BN and a third layer made of spacer SP.

Whole of the dam DM may be covered by the first inorganic encapsulation layer PAS1 and/or the second inorganic encapsulation layer PAS2. The organic encapsulation layer PCL may contact to some portions of the inner side surface of the dam DM. For example, the height of the side edge of the organic encapsulation layer PCL from bottom to the upper surface may be higher than the height of the first layer of the dam DM and lower than the height of the second layer of the dam DM. In order to limit the range of the organic encapsulation layer PCL by the dam DM, a trench TR may be further formed by patterning the bank BN and the planarization layer PLN. The trench TR is an element for confining the organic encapsulation layer PCL so that the organic encapsulation layer PCL does not overflow to the outside of dam DM, and is limited to the inside of the dam DM.

The height of the side edge of the organic encapsulation layer PCL from bottom to the upper surface may be set to be lower than the whole height of the dam DM. As a result, the first inorganic encapsulation layer PAS1 and the second inorganic encapsulation layer PAS2 are contact in surface each other at the upper surface of the dam DM and the outer side surface of the dam DM.

With such a structure, the electroluminescence display having a narrow-bezel structure, in which the area ratio of the display area AA to the total area of the display panel is increased, may be implemented by minimizing the width (or area) of the edge portion. The narrow bezel display has an advantage that the display area AA occupied a high ratio, thereby increasing the user's immersion.

Since the second non-display area IA2 without the gate driver 200 has no other elements other than the common power line CPL, there is no severe limitation in reducing the area of the second non-display area IA2. Meanwhile, the first no-display area IA1 may be an area that does not contribute to the narrow-bezel structure, because the first no-display area IA1 may have the driving integrated circuit 300 and be disposed at the lower side of the display panel. Therefore, in order to implement the narrow-bezel structure, it is important to reduce the area of the both sides on which the gate driver 200 is disposed, that is, the third non-display area IA3 and the fourth non-display area IA4.

However, reducing the areas of the third non-display area IA3 and the fourth non-display area IA4 is significantly limited because the gate driver 200 is disposed. A crack may be highly occurred in the step portions due to the multi-layered structure of the gate driver 200. In order to reduce the occurrence of cracks, the organic material layers may be applied. In case of that, moisture may penetrate from the outside through the organic material layers. In order to prevent moisture penetration, a nitride insulating layer may be used. However, there is a very high possibility that hydrogen particles emitted from the nitride layer will diffuse into the display area AA where the organic emission layer is disposed. These phenomena may occur more frequently as the areas of the third non-display area IA3 and the fourth non-display area IA4 are reduced.

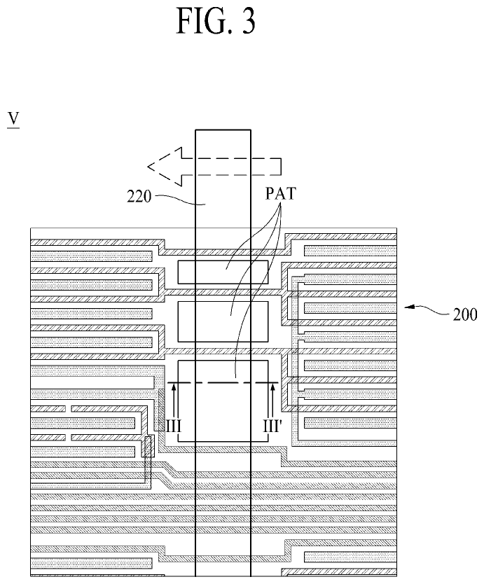

Therefore, in order to solve these problems, the electroluminescence display according to the present disclosure, as shown in FIG. 3, may include slit pattern 220 disposed in some area where the gate driver 200 is disposed. FIG. 3 is an enlarged plan view, illustrating a structure of a gate driver in the circular ‘V’ portion of FIG. 1.

The slit pattern 220 may be disposed at the middle portion of the area where the gate driver 200 is disposed. The gate driver 200 may include various thin film transistors for supplying the scan signals to the scan lines SL. The passivation layer PAS and the planarization layer PLN are deposited on these thin film transistors. In the narrow-bezel structure, the gaps or distances between the gate driver 200 and the edge of the dam DM and between the edge of the substrate SUB and the dam DM are very narrow. There is a very high possibility that moisture penetrate from the edge of the substrate SUB and diffuses into the display area AA.

To prevent this problem, the electroluminescence display according to the present disclosure includes the slit pattern 220 by partially removing the planarization layer PLN and the passivation layer PAS covering the gate driver 200. The slit pattern 220 is for blocking or broking a path through which moisture that has penetrated from the outside of the dam DM propagates toward the display area AA, as indicated by an arrow in FIG. 3.

Although the slit pattern 220 prevents moisture propagation, it may be weakness in which hydrogen particles may penetrate and diffuse in the step portion caused by the removal of the passivation layer PAS and the planarization layer PLN. Referring to FIG. 3 which is an enlarged view of the portion where the gate driver 200 is formed, although thin film transistors for gate driver 200 are densely formed, empty spaces there-between occupy a significant area between thin film transistors. Thin film transistors include source-drain electrodes, and the source-drain electrodes are made of molybdenum (Mo) and/or titanium (Ti). Therefore, even though hydrogen particles penetrate, molybdenum (Mo) and/or titanium (Ti) capture hydrogen particles, and the diffusion of the hydrogen particles may be suppressed.

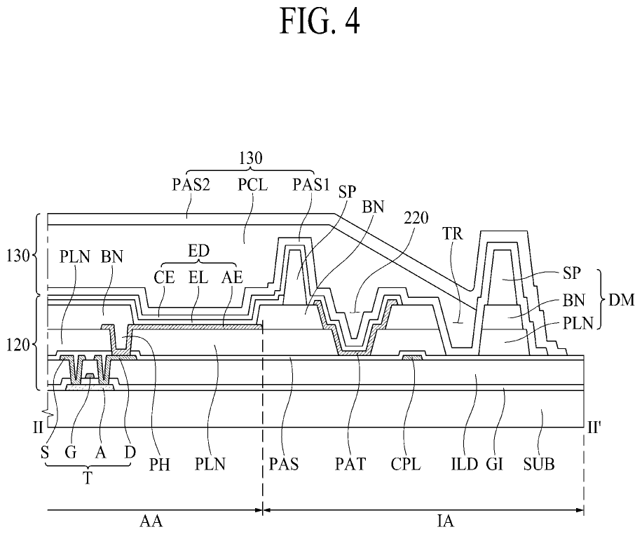

However, in the empty space region where the thin film transistor is not disposed but the slit pattern 220 is disposed, hydrogen particles easily penetrate and diffuse. Further, there is no element that may prevent the diffusion of the hydrogen particles. Accordingly, the present disclosure provides a structure in which the hydrogen particles penetrating from the slit pattern 220 may be absorbed. For example, as shown in FIG. 4, hydrogen particles penetrating from the slit pattern 220 may be absorbed by forming the protection pattern PAT in an empty space where there is no thin film transistor but the slit pattern 220 is formed. FIG. 4 is an enlarged cross-sectional view of portion where a protection pattern is formed, along cutting line II-IF in FIG. 1, illustrating a structure of an electroluminescence display according to the present disclosure.

Referring to FIG. 4, the electroluminescence display according to the present disclosure includes the slit pattern 220 in the non-display area where the gate driver 200 is formed. The slit pattern 220 may be deposed over the thin film transistors, and empty spaces where there is no thin film transistor. At the empty spaces where there is no thin film transistor, a protection pattern PAT is formed of the same material and at the same layer with the pixel driving electrode AE, after forming the slit pattern 220. The common electrode CE may be extended from the display area AA and connected to the protection pattern PAT. The protection pattern PAT may have an island shape which does not overlap with and contact the element of the gate driver 200 disposed surrounding the protection pattern PAT. The protection pattern PAT is made of a conductive material, so the static electricity may be caused and damaging to gate driver 200. Therefore, the protection pattern PAT may be connected to the common electrode CE to discharge the static electricity that may be concentrated in the protection pattern PAT.

Hereinafter, referring to various figures, several aspects for the protection pattern according to the present disclosure will be described. The following figures and descriptions show and explain the structure of the protection pattern PAT formed in the region where there is no thin film transistor in FIG. 3 showing the gate driver 200.

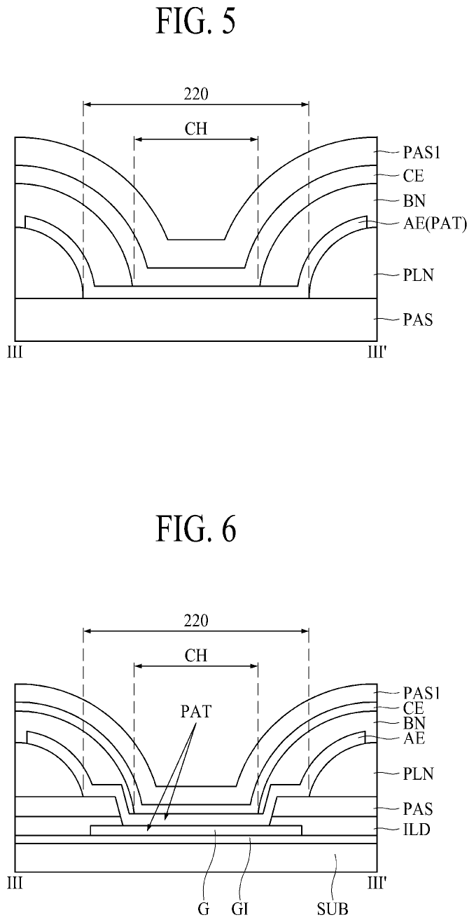

At first, referring to FIG. 5, the first aspect of the present disclosure will be described. FIG. 5 is a cross-sectional view, along cutting line in FIG. 3, illustrating a structure of an electroluminescence display according to the first aspect of the present disclosure.

Referring to FIG. 5, the planarization layer PLN is deposited on the passivation layer PAS covering the thin film transistor. By patterning some portions of the planarization layer PLN, the slit pattern 220 is formed. Since FIG. 5 shows where no thin film transistor is disposed, the thin film transistor is not illustrated under the passivation layer PAS. However, at other portions, thin film transistor may be disposed under the passivation layer PAS.

The protection pattern PAT is formed of the same material and at the same level with the pixel driving electrode AE as covering the slit pattern 220 formed at the planarization layer PLN. The protection pattern PAT may have a width wider than the slit pattern 220 to fully cover the etched side wall of the planarization layer PLN and the exposed surface of the passivation layer PAS from the planarization layer PLN.

The bank BN is formed on the protection pattern PAT. The bank BN may be formed to be continuously deposited to fully cover the protection pattern PAT and the slit pattern 220. However, when the protection pattern PAT is fully covered by the bank BN, the capacitance (by static electricity) may be concentrated at the protection pattern PAT. Since the capacitance may damage the planarization layer PLN or the bank BN, static electricity may be charged through the common electrode CE.

Therefore, the bank BN has a contact hole CH for exposing some portions of the protection pattern PAT. In particular, the contact hole CH may have narrow width than the slit pattern 220, and may be disposed within the slit pattern 220. As the bank BN is made of an organic material, the all step differences implemented as forming the slit pattern 220 and the protection pattern PAT. The common electrode CE extended from the display area AA may be disposed on the bank BN. The common electrode CE is connected to the protection pattern PAT through the contact hole CH.

The first inorganic encapsulation layer PAS1 is deposited on the common electrode CE. Even though it is not shown in FIGS., the organic encapsulation layer PCL and the second inorganic encapsulation layer PAS2 are deposited on the first inorganic encapsulation layer PAS1. For an example in which the gate driver 200 is disposed outside of the dam DM, the first inorganic encapsulation layer PAS1 and the second inorganic encapsulation layer PAS2 may be deposited on the common electrode CE. For another example in which the gate driver 200 is disposed inside from the dam DM, the first inorganic encapsulation layer PAS1, the organic encapsulation layer PCL and the second inorganic encapsulation layer PAS2 are sequentially deposited on the common electrode CE.

By the slit pattern 220 formed at the planarization layer PLN, moisture penetrating into the interface between the planarization layer PLN and the bank BN may be blocked. In addition, even when a crack is formed at the passivation layer PAS at the step portions where the patterned planarization layer PLN and the passivation layer PAS meet and the hydrogen contained in the passivation layer PAS is diffused, the protection pattern PAT that completely covers the slit pattern 220 may trap hydrogen particles or suppress the propagation speed of the hydrogen particles.

<Second Aspect>

Hereinafter, referring to FIG. 6, the second aspect of the present disclosure will be described. FIG. 6 is a cross-sectional view, along cutting line in FIG. 3, illustrating a structure of an electroluminescence display according to the second aspect of the present disclosure. The structure shown in FIG. 6 is very similar with that of the FIG. 5. The main difference is that the protection pattern PAT is made of the material same as the pixel driving electrode AE in the first aspect, but the protection pattern PAT of the second aspect further includes element formed of the material same as the thin film transistor in the second aspect.

For example, as shown in FIG. 4, the thin film transistor T is formed on the substrate SUB. Referring to FIG. 6, the protection pattern PAT may further include an element made of material same with the gate electrode of the thin film transistor.

The gate insulating layer GI is deposited on the substrate SUB. The semiconductor layer may be formed under the gate insulating layer GI. Since the slit pattern 220 is formed where there is no thin film transistor, there is no semiconductor layer under the gate insulating layer GI at the slit pattern 220. The gate electrode G is formed on the gate insulating layer GI. In the second aspect, a first layer of the protection pattern PAT is formed by patterning a same material as the gate electrode G and overlaps with the slit pattern 220.

In FIG. 6, The gate insulating layer GI is deposited over the entire of the substrate SUB and the gate electrode G is formed on the gate insulating layer GI. However, it is not limited thereto. The gate insulating layer GI may be formed as having the same shape with the gate electrode G.

The intermediate insulating layer ILD and the passivation layer PAS are sequentially deposited on the gate electrode G. By patterning the intermediate insulating layer ILD and the passivation layer PAS, most of middle portions of the first layer of the protection pattern PAT made of the same material with the gate electrode G are exposed.

The planarization layer PLN is deposited on the passivation layer PAS exposing the first layer of the protection pattern PAT. By removing some portions of the planarization layer PLN, the slit pattern 220 is formed. The slit pattern 220 may be formed to expose all exposed portions of the first layer of the protection pattern PAT from the passivation layer PAS and the intermediate insulating layer ILD.

A second layer of the protection pattern PAT is formed at the same layer with and of the same material with the pixel driving electrode AE to cover the slit pattern 220 formed at the planarization layer PLN. The second layer of the protection pattern PAT may have a width wider than the slit pattern 220 to fully cover the etched side wall of the planarization layer PLN, the side walls of the passivation layer PAS and the intermediate insulating layer ILD exposing the first layer of the protection pattern PAT, and the exposed surface of the first layer of the protection pattern PAT.

The bank BN is formed on the protection pattern PAT. A contact hole CH is formed at the bank BN for exposing the second layer of the protection pattern PAT. The common electrode CE extended from the display area AA may be disposed on the bank BN. The common electrode CE is connected to the second layer of the protection pattern PAT through the contact hole CH.

The first inorganic encapsulation layer PAS1 is deposited on the common electrode CE. For a case of which the gate driver 200 is disposed inside from the dam DM, the first inorganic encapsulation layer PAS1, the organic encapsulation layer PCL and the second inorganic encapsulation layer PAS2 are sequentially deposited on the common electrode CE.

By the slit pattern 220 formed at the planarization layer PLN, moisture penetrating into the interface between the planarization layer PLN and the bank BN may be blocked. In addition, even when a crack is formed at the passivation layer PAS at the step portions where the patterned planarization layer PLN and the passivation layer PAS meet and the hydrogen contained in the passivation layer PAS is diffused, the protection pattern PAT that completely covers the slit pattern 220 may trap hydrogen particles or suppress the propagation speed of the hydrogen particles.

In addition, the protection pattern PAT have the double stacked structure in which a first layer made of the same material with the gate electrode G and a second layer made of the same material with the pixel driving electrode AE. In this case, by capturing the hydrogen particles using molybdenum (Mo) and/or titanium (Ti) included in the gate electrode G to suppress the propagating of the hydrogen particles, the driving element including the oxide semiconductor material may be protected.

<Third Aspect>

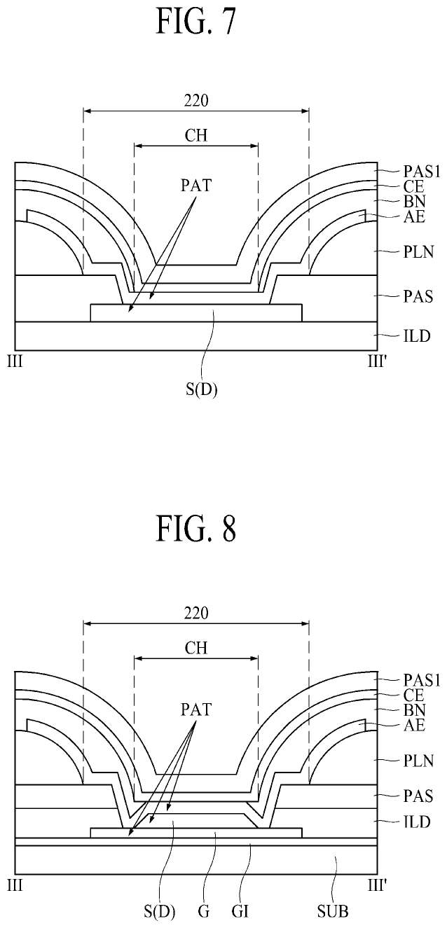

Hereinafter, referring to FIG. 7, the third aspect of the present disclosure will be described. FIG. 7 is a cross-sectional view, along cutting line in FIG. 3, illustrating a structure of an electroluminescence display according to the third aspect of the present disclosure. The structure shown in FIG. 7 is very similar with that of the FIG. 6. Therefore, the description for the same structure will not be duplicated, the descriptions for the different points will be explained.

For example, in the second aspect, the first layer of the protection pattern PAT is formed of the same material with the gate electrode G. In the third aspect, the first layer of the protection pattern PAT is made of the same material with the source-drain electrode S-D of the thin film transistor T.

The intermediate insulating layer ILD is deposited on the substrate SUB. Even though it is not shown in the figures, the gate insulating layer GI is deposited below the intermediate insulating layer ILD. On the intermediate insulating layer ILD, the source electrode S (and/or drain electrode D) of the thin film transistor T is formed. A first layer of the protection pattern PAT is formed at the same layer with and of the same material with the source electrode S at the area where the slit pattern 220 is formed.

The passivation layer PAS is deposited on the first layer of the protection pattern PAT. By patterning the passivation layer PAS, the first layer of the protection pattern PAT made of the same material with the source electrode S is exposed.

The planarization layer PLN is deposited on the passivation layer PAS exposing the first layer of the protection pattern PAT. By removing some portions of the planarization layer PLN, the slit pattern 220 is formed. The slit pattern 220 may be formed to expose all exposed portion of the first layer of the protection pattern PAT from the passivation layer PAS.

A second layer of the protection pattern PAT is formed at the same layer with and of the same material with the pixel driving electrode AE to cover the slit pattern 220 formed at the planarization layer PLN. The second layer of the protection pattern PAT may have a width wider than the slit pattern 220 to fully cover the etched side wall of the planarization layer PLN, the side walls of the passivation layer PAS exposing the first layer of the protection pattern PAT, and the exposed surface of the first layer of the protection pattern PAT.

The bank BN is formed on the protection pattern PAT. A contact hole CH is formed at the bank BN for exposing the second layer of the protection pattern PAT. The common electrode CE extended from the display area AA may be disposed on the bank BN. The common electrode CE is connected to the second layer of the protection pattern PAT through the contact hole CH.

The first inorganic encapsulation layer PAS1 is deposited on the common electrode CE. For a case of which the gate driver 200 is disposed inside from the dam DM, the first inorganic encapsulation layer PAS1, the organic encapsulation layer PCL and the second inorganic encapsulation layer PAS2 are sequentially deposited on the common electrode CE.

By the slit pattern 220 formed at the planarization layer PLN, moisture penetrating into the interface between the planarization layer PLN and the bank BN may be blocked. In addition, even when a crack is formed at the passivation layer PAS at the step portions where the patterned planarization layer PLN and the passivation layer PAS meet and the hydrogen contained in the passivation layer PAS is diffused, the protection pattern PAT that formed at the slit pattern 220 may trap hydrogen particles or suppress the propagation speed of the hydrogen particles.

In addition, the protection pattern PAT have the double stacked structure in which a first layer made of the same material with the source electrode S and a second layer made of the same material with the pixel driving electrode AE. In this case, by capturing the hydrogen particles using molybdenum (Mo) and/or titanium (Ti) included in the source electrode S to suppress the propagating of the hydrogen particles, the driving element including the oxide semiconductor material may be protected.

<Fourth Aspect>

Hereinafter, referring to FIG. 8, the fourth aspect of the present disclosure will be described. FIG. 8 is a cross-sectional view, along cutting line in FIG. 3, illustrating a structure of an electroluminescence display according to the fourth aspect of the present disclosure. The structure shown in FIG. 8 is very similar with that of the FIGS. 6 and 7. Therefore, the description for the same structure will not be duplicated, the descriptions for the different points will be explained.

The fourth aspect has a feature in which a first layer of the protection pattern PAT is formed of the same material with the gate electrode G, a second layer of the protection pattern PAT is formed of the same material with the source-drain electrode S-D, and a third layer of the protection pattern PAT is formed of the same material with the pixel driving electrode AE.

The gate insulating layer GI is deposited on the substrate SUB. On the gate insulating layer GI, the gate electrode G of the thin film transistor T is formed. At the region for the slit pattern 220, the first layer of the protection pattern PAT is formed of the same material with and at the same layer with the gate electrode G. In FIG. 6, The gate insulating layer GI is deposited over the entire of the substrate SUB and the gate electrode G is formed on the gate insulating layer GI. However, it is not limited thereto. The gate insulating layer GI may be formed as having the same shape with the gate electrode G.

The intermediate insulating layer ILD is deposited on the first layer of the protection pattern PAT. By patterning the intermediate insulating layer ILD, most of middle portions of the first layer of the protection pattern PAT is exposed. On the central portions of the exposed first layer of the protection pattern PAT, the second layer of the protection pattern PAT is formed of the same material with the source electrode S of the thin film transistor T.

The passivation layer PAS is deposited on the first layer and the second layer of the protection pattern PAT. By patterning the passivation layer PAS, the first layer and the second layer of the protection pattern PAT are exposed. In particular, the passivation layer PAS may be patterned so that the second layer of the protection pattern PAT is fully exposed, and some portion of the first layer surrounding the second layer is exposed.

The planarization layer PLN is deposited on the passivation layer PAS exposing the first layer and the second layer of the protection pattern PAT. By removing some portions of the planarization layer PLN, the slit pattern 220 is formed. The slit pattern 220 may be formed to expose all exposed portions of the first layer and the second layer of the protection pattern PAT from the passivation layer PAS.

The third layer of the protection pattern PAT is formed at the same layer with and of the same material with the pixel driving electrode AE to cover the slit pattern 220 formed at the planarization layer PLN. The third layer of the protection pattern PAT may have a width wider than the slit pattern 220 to fully cover the etched side wall of the planarization layer PLN, the side walls of the passivation layer PAS exposing the first layer and the second layer of the protection pattern PAT, and the exposed surface of the first layer and the second layer of the protection pattern PAT.

The bank BN is formed on the protection pattern PAT. A contact hole CH is formed at the bank BN for exposing the second layer of the protection pattern PAT. The common electrode CE extended from the display area AA may be disposed on the bank BN. The common electrode CE is connected to the second layer of the protection pattern PAT through the contact hole CH.

The first inorganic encapsulation layer PAS1 is deposited on the common electrode CE. For a case of which the gate driver 200 is disposed inside from the dam DM, the first inorganic encapsulation layer PAS1, the organic encapsulation layer PCL and the second inorganic encapsulation layer PAS2 are sequentially deposited on the common electrode CE.

By the slit pattern 220 formed at the planarization layer PLN, moisture penetrating into the interface between the planarization layer PLN and the bank BN may be blocked. In addition, even when a crack is formed at the passivation layer PAS at the step portions where the patterned planarization layer PLN and the passivation layer PAS meet and the hydrogen contained in the passivation layer PAS is diffused, the protection pattern PAT that completely covers the slit pattern 220 may trap hydrogen particles or suppress the propagation speed of the hydrogen particles.

In addition, the protection pattern PAT have the triple stacked structure in which a first layer made of the same material with the gate electrode G, a second layer made of the same material with the source electrode S and a third layer made of the same material with the pixel driving electrode AE. In this case, by capturing the hydrogen particles using molybdenum (Mo) and/or titanium (Ti) included in the gate electrode G and/or source electrode S to suppress the propagating of the hydrogen particles, the driving element including the oxide semiconductor material may be protected.

<Fifth Aspect>

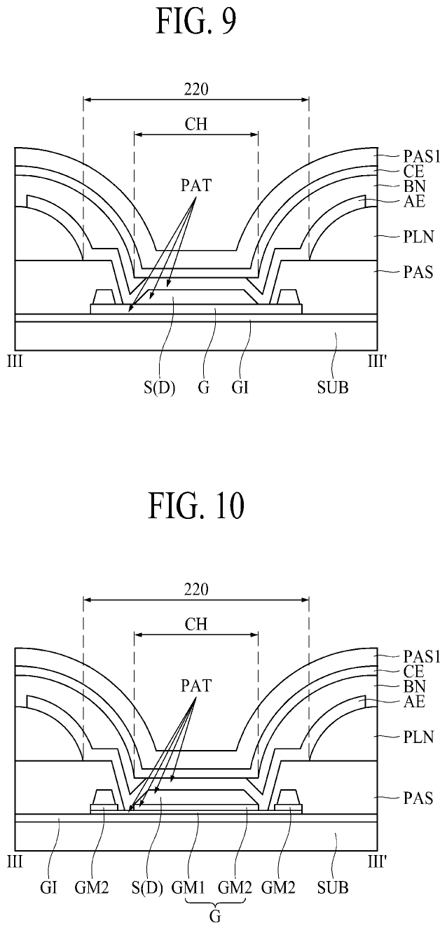

Hereinafter, referring to FIG. 9, the fifth aspect of the present disclosure will be described. FIG. 9 is a cross-sectional view, along cutting line in FIG. 3, illustrating a structure of an electroluminescence display according to the fifth aspect of the present disclosure. The structure for the fifth aspect shown in FIG. 9 is very similar with the structure for fourth aspect shown in FIG. 8.

The difference is on the shape of the second layer of the protection pattern PAT. In the fourth aspect, the second layer of the protection pattern PAT formed of the source electrode S is disposed at the central portion of the first layer of the protection pattern PAT. In the fifth aspect, the second layer of the protection pattern PAT may have the same shape with the first layer of the protection pattern PAT, and be stacked on the first layer of the protection pattern PAT. After that, removing some edge portions of the second layer of the protection pattern PAT, some portions of the first layer of the protection pattern PAT is exposed. The third layer of the protection pattern PAT contacts the exposed portion of the first layer of the protection pattern PAT from the second layer of the protection pattern PAT, and contacts the surfaces of the second layer of the protection pattern PAT.

Since the first layer and the second layer have the same shape, the intermediate insulating layer ILD may be removed from the area where the gate driver 200 is formed. The edge portions of the second layer of the protection pattern PAT which are removed are covered by the passivation layer PAS, the middle portions are exposed by patterning the passivation layer PAS.

With this structure, the surface areas of the first layer and the second layer of the protection pattern PAT which contact the third layer of the protection pattern PAT may be more largely ensured than the first to third aspects as possible. Therefore, the ability to capture hydrogen particles may be further improved by the first layer and the second layer of the protection pattern PAT including molybdenum (Mo) and/or titanium (Ti) as the hydrogen particles penetrate and diffuse.

Other elements of the fifth aspect are same with those of the fourth aspect, so the same description is not duplicated.

<Sixth Aspect>

Hereinafter, referring to FIG. 10, the sixth aspect of the present disclosure will be described. FIG. 10 is a cross-sectional view, along cutting line in FIG. 3, illustrating a structure of an electroluminescence display according to the sixth aspect of the present disclosure. The structure for the sixth aspect shown in FIG. 10 is very similar with the structures for fifth aspect shown in FIG. 9 and for fourth aspect shown in FIG. 8.

The difference is on the structure of the first layer of the protection pattern PAT. In the fifth aspect, the first layer of the protection pattern PAT has the single layered structure in which the same material with the gate electrode G is used for the first layer. In the sixth aspect, the first layer of the protection pattern PAT has the double layered structure.

The first layer of the protection pattern PAT includes a first metal layer GM1 and a second metal layer GM2 sequentially stacked on the gate insulating layer GI. The first metal layer GM1 is made of molybdenum (Mo)-titanium (Ti) alloy, and the second metal layer GM2 is made of copper (Cu). The stacking order of the first metal layer GM1 and the second metal layer GM2 may be reversed. That is, the first metal layer GM1 may be made of copper (Cu) and the second metal layer GM2 may be made of molybdenum (Mo)-titanium (Ti) alloy.

Further, in the sixth aspect, some portions of the surface of the first metal layer GM1 may be exposed as patterning the second layer of the protection pattern PAT covering the first layer of the protection pattern PAT to expose some surfaces of the first layer of the protection pattern PAT. By exposing the first metal layer GM1 including molybdenum (Mo)-titanium (Ti) alloy, the ability to capture hydrogen particles may be further improved.

Other elements of the sixth aspect are same with those of the fourth aspect, so the same description is not duplicated.

Features, structures, effects and so on described in the above described examples of the present disclosure are included in at least one example of the present disclosure, and are not necessarily limited to only one example. Furthermore, features, structures, effects and so on exemplified in at least one example of the present disclosure may be implemented by combining or modifying other examples by a person having ordinary skilled in this field. Therefore, contents related to such combinations and modifications should be interpreted as being included in the scope of the present application.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents. These and other changes can be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the disclosure.

What is claimed is:

1. An electroluminescence display apparatus comprising:
a substrate including a display area and a non-display area surrounding the display area;
a light emitting element disposed in the display area;
a gate driver disposed at the non-display area;
a slit pattern overlapping with the gate driver; and
a protection pattern overlapping with an empty space of the gate driver in the slit pattern,
wherein the slit pattern has a shape of a trench formed at a planarization layer covering the gate driver, and
wherein the protection pattern includes a same material as a part of the light emitting element and a part of the gate driver.

2. The electroluminescence display apparatus according to claim 1, wherein the gate driver comprises a plurality of thin film transistors,
the slit pattern overlap withs the thin film transistors and empty spaces having no thin film transistor, and
the protection pattern overlaps with the slit pattern which overlaps with the empty spaces.

3. The electroluminescence display apparatus according to claim 1, wherein the light emitting element includes:
a pixel driving electrode disposed on the planarization layer;
a bank defining an emission area at middle portions of the pixel driving electrode;
an emission layer disposed on the pixel driving electrode; and
a common electrode disposed on the emission layer,
wherein the protection pattern covers the slit pattern, is disposed on a passivation layer covering the gate driver, and includes a same material as the pixel driving electrode,
wherein the bank includes a contact hole exposing a central portion of the protection pattern, and
wherein the common electrode extends from the display area to the non-display area and contacts the protection pattern via the contact hole.

4. The electroluminescence display apparatus according to claim 3, wherein the protection pattern includes:
a first layer including a same material as an element of the gate driver; and
a second layer including a same material as the pixel driving electrode on the first layer,
wherein the second layer contacts the first layer.

5. The electroluminescence display apparatus according to claim 4, wherein the first layer includes one of molybdenum, titanium and molybdenum-titanium alloy.

6. The electroluminescence display apparatus according to claim 4, wherein the first layer is disposed on a gate insulating layer covering the substrate and includes a same material as a gate electrode of the gate driver, and
wherein the second layer contacts the first layer through the intermediate insulating layer and the passivation layer covering the first layer.

7. The electroluminescence display apparatus according to claim 4, wherein the first layer is disposed on an intermediate insulating layer covering the substrate and includes a same material as a source electrode of the gate driver, and
wherein the second layer contacts the first layer through the passivation layer covering the first layer.

8. The electroluminescence display apparatus according to claim 3, wherein the protection pattern includes:
a first layer including a same material as a gate electrode of the gate driver;
a second layer disposed on the first layer and including a same material as a source electrode of the gate driver; and
a third layer disposed on the second layer and including a same material as the pixel driving electrode, and
wherein the second layer and the third layer contact the first layer.

9. The electroluminescence display apparatus according to claim 8, wherein the second layer contacts a central portion of the first layer and exposes circumference portion of the first layer, and
wherein the third layer contacts the exposed circumference portion of the first layer and the second layer.

10. The electroluminescence display apparatus according to claim 8, wherein the first layer and the second layer have a same shape and a portion of the first layer is exposed from circumference of the second layer, and
wherein the third layer contacts the second layer and the exposed portion of the first layer from the second layer.

11. The electroluminescence display apparatus according to claim 8, wherein the first layer and the second layer include one of molybdenum, titanium and molybdenum-titanium alloy.

12. The electroluminescence display apparatus according to claim 8, wherein the first layer includes:
a first metal layer formed on the gate insulating layer; and
a second metal layer formed on the first metal layer,
wherein the first metal layer is exposed from circumference of the second layer and the second metal layer, and
wherein the third layer contacts the second layer and the exposed portion of the first metal layer from the second layer and the second metal layer.

13. The electroluminescence display apparatus according to claim 12, wherein the first metal layer includes one of molybdenum, titanium and molybdenum-titanium alloy, and
wherein the second metal layer includes one of aluminum and copper.

14. The electroluminescence display apparatus according to claim 1, further comprising:
a dam disposed outside the gate driver in the non-display area and surrounding the display area; and
an encapsulation layer disposed on the common electrode.

15. The electroluminescence display apparatus according to claim 14, wherein the encapsulation layer includes:
a first inorganic encapsulation layer covering the display area and the non-display area, an inside wall surface of the dam, an upper surface of the dam, and an outer wall surface of the dam;
an organic encapsulation layer disposed on the first inorganic encapsulation layer, and contacting a portion of the inside wall surface of the dam; and
a second inorganic encapsulation layer disposed on the organic encapsulation layer, and contacting the first inorganic encapsulation layer at the upper surface of the dam and the outer wall surface of the dam.

16. An electroluminescence display apparatus comprising:
a substrate including a display area and a non-display area surrounding the display area;
a gate driver and a slit pattern disposed at the non-display area, wherein the gate driver comprises a plurality of thin film transistors, and the slit pattern is disposed over the thin film transistors and empty spaces where there is no thin film transistor; and
a protection pattern covering the slit pattern located over the empty spaces, and includes one of molybdenum, titanium and molybdenum-titanium alloy.
